(19) United States
(12) Patent Application Publication
(10) Pub. No.: US 2026/0351515 A1
(43) Pub. Date: Nov. 5, 2026

(54) METHOD FOR OPERATING AN ELECTRON BEAM MICROSCOPE, AND ELECTRON BEAM MICROSCOPE

(71) Applicant: Carl Zeiss Microscopy GmbH, Jena (DE)

(72) Inventor: Björn GAMM, Königsbronn (DE)

(21) Appl. No.: 19/661,103

(22) Filed: Apr. 28, 2026

(30) Foreign Application Priority Data
Apr. 30, 2025 (DE) 10 2025 116 803.2

(51) Int. Cl. H01J 37/244; H01J 37/26

(52) U.S. Cl. CPC H01J 37/244; H01J 37/265; H01J 2237/0473; H01J 2237/2443; H01J 2237/24475; H01J 2237/2448

(57) ABSTRACT

A method comprises: recording a first image of a sample while an acceleration voltage is applied between an electron source and the sample and a beam tube voltage, which is an electric voltage between the beam tube and the sample, is applied according to a first value; and recording a second image of the sample while the acceleration voltage is applied between the electron source and the sample and the beam tube voltage is applied according to a second value. Recording comprises: directing an electron beam from the electron source, propagating through an interior of the beam tube, onto the sample and generating a detection signal via a detector, which comprises a scintillator, arranged in the interior of the beam tube, for converting electrons emitted by the sample into light and a light detector for generating the detection signal based on the light generated by the scintillator.

### CROSS-REFERENCE TO RELATED APPLICATIONS

This application claims benefit under 35 U.S.C. § 119 to German Application No. 10 2025 116 803.2, filed Apr. 30, 2025. The entire disclosure of this application is incorporated by reference herein.

### FIELD

The present disclosure relates to a method for operating an electron beam microscope, and to an electron beam microscope.

### BACKGROUND

Electron beam microscopes can be used for the analysis of samples. For this purpose, for example, an image of the sample is recorded, wherein the image is recorded by virtue of an electron beam being directed successively onto a multiplicity of different locations of the sample and interaction products of an interaction of the electron beam with the sample being detected. Examples of such interaction products are secondary electrons and backscatter electrons, which are also referred to as backscattered electrons.

Secondary electrons have a relatively low kinetic energy (emission energy) upon emission by the sample. By way of example, the emission energy of secondary electrons is in the range of 0 eV to approximately 100 eV. Herein, a secondary electron image denotes an image of a sample obtained by detection of (almost exclusively or at least predominantly) secondary electrons.

Backscattered electrons are electrons of the electron beam which are substantially elastically scattered at the sample. Therefore, when emitted by the sample, backscattered electrons have a kinetic energy (emission energy) which, in general, deviates at most slightly from a landing energy. The landing energy denotes the kinetic energy with which the electrons of the electron beam are incident on the sample. Herein, a backscattered electron image denotes an image of a sample obtained by detection of (almost exclusively or at least predominantly) backscattered electrons.

Secondary electron images and backscattered electron images of the same sample can represent different properties of the sample. Therefore, for the analysis of a sample, it may be desirable to have both types of images available.

In order to be able to provide both a secondary electron image and a backscattered electron image of the same sample, an example of a conventional electron beam microscope comprises two separate detectors: a detector serving to detect (almost exclusively or at least predominantly) secondary electrons, and a further detector serving to detect (almost exclusively or at least predominantly) backscattered electrons. Such configurations with a plurality of detectors can be relatively complex and relatively cost-intensive.

### SUMMARY

The present disclosure seeks to provide a possibility for recording secondary electron images and backscattered electron images using simpler and more cost-effective approach.

One aspect of the disclosure relates to methods for operating an electron beam microscope comprising an electron source and a beam tube. The method comprises: recording a first image of a sample while an electric acceleration voltage is applied between the electron source and the sample and a beam tube voltage, which is an electric voltage between the beam tube and the sample, is applied according to a first value; and recording a second image of the sample while the acceleration voltage is applied between the electron source and the sample and the beam tube voltage is applied according to a second value. Recording the first image and the second image in each case comprises: directing an electron beam which is provided by the electron source and propagates through an interior of the beam tube successively onto a multiplicity of different locations of the sample and generating a detection signal via a detector, which comprises a scintillator, arranged in the interior of the beam tube, for converting electrons emitted by the sample into light and a light detector for generating the detection signal on the basis of the light generated by the scintillator. The first value and the second value of the beam tube voltage are different from one another and are chosen such that a value of a backscattered electron-secondary electron contribution ratio when recording the first image is greater than the value of the backscattered electron-secondary electron contribution ratio when recording the second image. The backscattered electron-secondary electron contribution ratio indicates a ratio of a contribution of backscattered electrons to the detection signal to a contribution of secondary electrons to the detection signal when recording a specific image. Secondary electrons are electrons emitted by the sample with an energy of at most 100 eV. Backscattered electrons are electrons emitted by the sample with an energy which differs from a product of electron elementary charge and the acceleration voltage by at most 500 eV.

A further aspect of the disclosure relates to an electron beam microscope for recording images of a sample, comprising: an electron source configured to provide an electron beam; a beam tube surrounding an interior, in which the electron beam propagates during operation; a deflection system configured to deflect the electron beam transversely with respect to a direction of propagation of the electron beam; a detector comprising a scintillator and a light detector, wherein the scintillator is arranged in the interior of the beam tube and is configured to convert electrons emitted by the sample and incident on the scintillator into light, and wherein the light detector is configured to detect the light generated by the scintillator; a driver system configured to apply an electric acceleration voltage between the electron source and the sample and to apply a variably adjustable electric voltage between the beam tube and the sample; and a controller configured to carry out the method according to the disclosure.

The acceleration voltage between the electron source and the sample can accelerate the electron beam provided by the electron source to the sample.

The beam tube voltage can accelerate electrons emitted by the sample, which comprise both secondary electrons and backscattered electrons, between the sample and the beam tube (to different extents). The energy of incidence of the electrons emitted by the sample on the scintillator, i.e. the kinetic energy with which these electrons are incident on the scintillator, can therefore be obtained as the sum of the emission energy, i.e. the kinetic energy with which the electrons are emitted by the sample, and the energy which is absorbed as a result of acceleration in an electric field generated by the beam tube voltage between the sample and the beam tube. That means that the energy of incidence can be directly influenced by the electric voltage between the sample and the beam tube.

The scintillator can have an energy-dependent conversion efficiency. That means that the efficiency with which the scintillator converts an incident electron into light can vary as a function of the energy of incidence.

By varying the beam tube voltage, it is therefore possible to adapt the energy of incidence of the electrons emitted by the sample on the scintillator in such a way that the electrons are converted into light by the scintillator with a desired conversion efficiency. For example, it is possible to adapt the conversion efficiency with which backscattered electrons are converted by the scintillator and the conversion efficiency with which secondary electrons are converted by the scintillator by changing the beam tube voltage.

The light detector can detect the light generated by the scintillator and can generate the detection signal on the basis of the detected light. The detection signal represents for example an intensity of the light generated by the scintillator. By way of example, the detection signal can represent a total intensity of the light which is detected by the light detector during the recording of an individual image. The detection signal is typically dependent on the conversion efficiency of the scintillator and on the detection efficiency of the light detector.

The detection signal generated by the detector when recording the first image and the second image can be composed of substantially two contributions: a first contribution generated by backscattered electrons, and a second contribution generated by secondary electrons. The contribution of the backscattered electrons to the detection signal consists in the light which is generated by backscattered electrons in the scintillator and is detected by the light detector. The contribution of the secondary electrons to the detection signal includes (or consists of) the light which is generated by secondary electrons in the scintillator and can be detected by the light detector. The backscattered electron-secondary electron contribution ratio can indicate a ratio of the contribution of backscattered electrons to the detection signal to a contribution of secondary electrons to the detection signal when recording a specific image.

The first value and the second value of the beam tube voltage can be chosen such that a value of the backscattered electron-secondary electron contribution ratio when recording the first image is greater than the value of the backscattered electron-secondary electron contribution ratio when recording the second image. That means that the first image can be based on the detection of backscattered electrons to a higher degree than the second image.

By way of example, the first value of the beam tube voltage is chosen such that the first image is a backscattered electron image. The backscattered electron image can be distinguished by the fact that it can be based predominantly on the detection of backscattered electrons rather than predominantly on the detection of secondary electrons.

By way of example, the second value of the beam tube voltage is chosen such that the second image is a secondary electron image. The secondary electron image can be distinguished by the fact that it can be based predominantly on the detection of secondary electrons rather than predominantly on the detection of backscattered electrons.

### BRIEF DESCRIPTION OF THE DRAWINGS

Embodiments of the disclosure are explained in more detail below with reference to figures, in which:

FIG. 1 shows a schematic illustration of an electron beam microscope;

FIG. 2 shows a schematic illustration of a detector of the electron beam microscope;

FIG. 3 shows a flowchart showing a method for operating the electron beam microscope;

FIG. 4 shows a first schematic illustration of an energy-dependent conversion efficiency of a scintillator of the detector and of a spectrum of electrons when incident on the scintillator with the use of a beam tube voltage according to a first value; and

FIG. 5 shows a second schematic illustration of an energy-dependent conversion efficiency of the scintillator of the detector and of the spectrum of the electrons when incident on the scintillator with the use of a beam tube voltage according to a second value.

### DETAILED DESCRIPTION

### Electron Beam Microscope

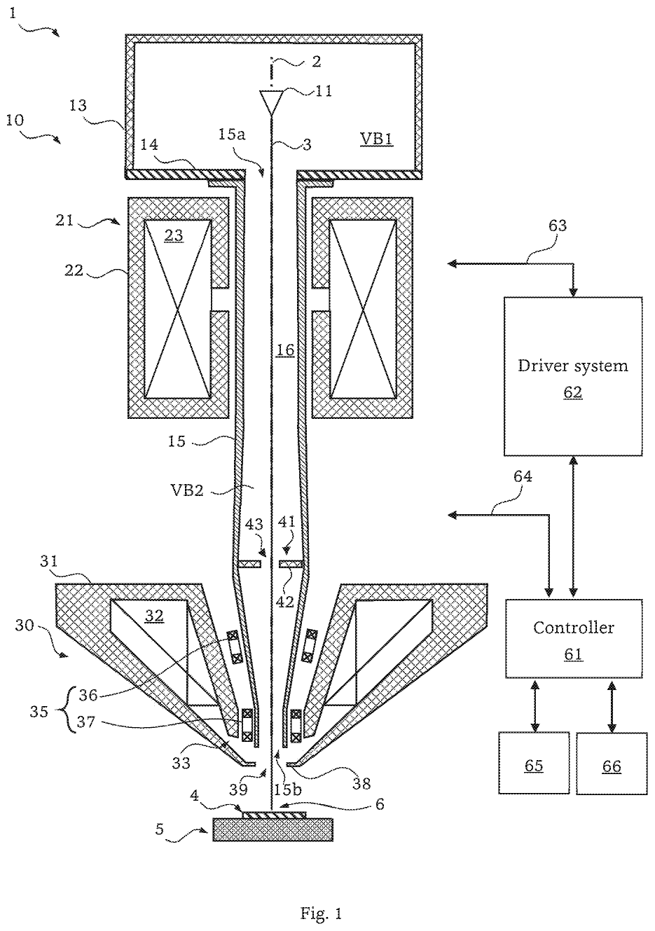

FIG. 1 shows a schematic illustration of an electron beam microscope 1, which can be used to carry out the method according to the disclosure. The electron beam microscope 1 serves to record images of a sample 4 arranged in a work region 6 of the electron beam microscope 1.

The electron beam microscope 1 comprises an electron beam column 10. The electron beam column 10 comprises an electron source 11 configured to provide an electron beam 3 (i.e. a beam of electrons). An electric potential can be applied to the electron source 11.

The electron source 11 is arranged in a first vacuum region VB1, in which a first vacuum is formed during operation. For example, the first vacuum is established by a first housing section 13, a second housing section 14 and a pump, not illustrated, which evacuates the vacuum region VB1. The first housing section 13 is designed for example as an electrical conductor, whereas the second housing section 14 is an electrical insulator.

The electron beam column 10 furthermore comprises a beam tube 15 arranged downstream of the electron source 11 along the propagation direction of the electron beam 3. In other words, the beam tube 15 is arranged between the electron source 11 and the work region 6. In the example shown in FIG. 1, the beam tube 15, viewed along a central axis 2 of the electron beam column 10, extends from the housing section 14 as far as into the inside of an objective lens 30. The beam tube 15 comprises a tubular body having a first opening 15a at a first end and having a second opening 15b at a second end. During operation, the electron beam 3 coming from the electron source 11 enters an interior 16 of the beam tube 15 through the first opening 15a, travels in the interior 16 of the beam tube 15 from the first opening 15a to the second opening 15b and emerges from the interior 16 of the beam tube 15 through the second opening 15b.

An electric potential can be applied to the beam tube 15. During operation, the electric potential of the beam tube 15 and the electric potential of the electron source 11 are generated in such a way that an electric field is generated between the beam tube 15 and the electron source 11, the electric field accelerating the electrons of the electron beam 3 from the electron source 11 to the beam tube 15.

During operation, the electron beam microscope 1 has in the beam tube 15 a second vacuum region VB2, in which a second vacuum is formed, which can be different from the first vacuum in the first vacuum region VB1. For example, the second vacuum region VB2 is established by the beam tube 15 and a pump, not illustrated, which evacuates the vacuum region VB2.

The electron beam column 10 furthermore comprises a condenser lens 21 configured to generate a magnetic field. The condenser lens 21 comprises a magnetic core 22 for guiding the magnetic field and an excitation coil 23 for generating the magnetic field. During operation, an electric current is supplied to the excitation coil 23, and generates the magnetic field. The magnetic core 22 is designed to be substantially rotationally symmetric about the central axis 2. The magnetic core 22 is arranged completely outside the beam tube 15. The magnetic core 22 is arranged downstream of the first opening 15a of the beam tube 15 along the propagation direction of the electron beam 3. In other words, the magnetic core 22 is arranged between the electron source 11 and the objective lens 30.

During operation, the condenser lens 21 causes a change in a divergence angle of the electron beam 3 by focusing the electron beam 3. This enables a beam diameter of the electron beam 3 to be varied. For example, the beam diameter of the electron beam 3 can be adapted to an effective range of the objective lens 30.

The electron beam column 10 furthermore comprises the objective lens 30 arranged downstream of the condenser lens 21 along the propagation direction of the electron beam 3. In other words, the objective lens 30 is arranged between the condenser lens 21 and the work region 6. The objective lens 30 is arranged on the second end of the beam tube 15. The objective lens 30 is configured to focus the electron beam 3 on the work region 6. The sample 4 can be arranged in the work region 6, for example on a sample holder 5. The work region 6 is situated outside the electron beam column 10. Accordingly, the objective lens 30 is configured to focus the electron beam 3 on the sample 4.

Although not shown in FIG. 1, the electron beam microscope 1 furthermore comprises a vacuum chamber into which the electron beam 3 enters and in which the sample 4 and the work region 6 are arranged.

For example, the objective lens 30 comprises a magnetic core 31 and an excitation coil 32. During operation, an electric current is supplied to the excitation coil 32, as a result of which a magnetic field is generated which is guided by the magnetic core 31. The magnetic field leaves the magnetic core 31 from a gap 33 in the magnetic core 31 and is formed, when excited appropriately, such that the magnetic field has a focusing effect on the electron beam 3.

The electron beam column 10 furthermore comprises a deflection system 35. The deflection system 35 is arranged along the central axis 2 and level with the objective lens 30. The deflection system 35 is configured to deflect the electron beam 3 in the radial direction (i.e. transversely with respect to the central axis 2), in order thereby to direct the electron beam 3 onto different locations of the work region 6 and hence onto different locations of the sample 4. In the example shown in FIG. 1, the deflection system 35 comprises two deflection units 36 and 37, which are formed from coils. In the example shown in FIG. 1, the coils of the deflection units 36 and 37 are arranged between the beam tube 15 and the magnetic core 31 of the objective lens 30. The two deflection units 36 and 37 are arranged in a manner distributed along the central axis 2. During operation, electric currents are supplied to the deflection units 36 and 37, as a result of which magnetic fields are generated which deflect the electron beam 3 in the radial direction.

The electron beam column 10 furthermore comprises a terminating stop 38, which is arranged downstream of the beam tube 15 along the propagation direction of the electron beam 3 and has an aperture 39. In other words, the terminating stop 38 is arranged between the beam tube 15 and the work region 6. During operation, the electron beam 3 passes through the aperture 39 and enters the vacuum chamber through the latter. An electric potential can be applied to the terminating stop 38. During operation, the electric potential of the terminating stop 38 and the electric potential of the beam tube 15 are generated in such a way that an electric field which acts on the electron beam 3 is generated between the terminating stop 38 and the beam tube 15. However, the terminating stop 38 and the beam tube 15 can alternatively have the same electric potential. In the example shown in FIG. 1, the terminating stop 38 is formed by the magnetic core 31. However, this is merely by way of example. The terminating stop 38 can be separate and electrically insulated from the magnetic core 31.

The electron beam microscope 1 furthermore comprises the sample holder 5, on which the sample 4 can be positioned. An electric potential can be applied to the sample holder 5 or the sample 4. A case in which an electric potential is applied to the sample 4 is described herein as an example.

The electric voltage between the electric potential of the sample 4 and the electric potential of the electron source 11 (i.e. the electric voltage between the sample 4 and the electron source 11) is referred to as acceleration voltage U0. The acceleration voltage U0 determines the kinetic energy with which the electrons of the electron beam 3 are incident on the sample 4. The kinetic energy with which the electrons of the electron beam 3 are incident on the sample 4 is also referred to as the landing energy LE and is calculated as LE=e·U0, where e is the absolute value of the electron elementary charge. During operation, the electric potential of the sample 4 and the electric potential of the electron source 11 and hence the acceleration voltage U0 are chosen and set such that the electron beam 3 is accelerated to the sample 4.

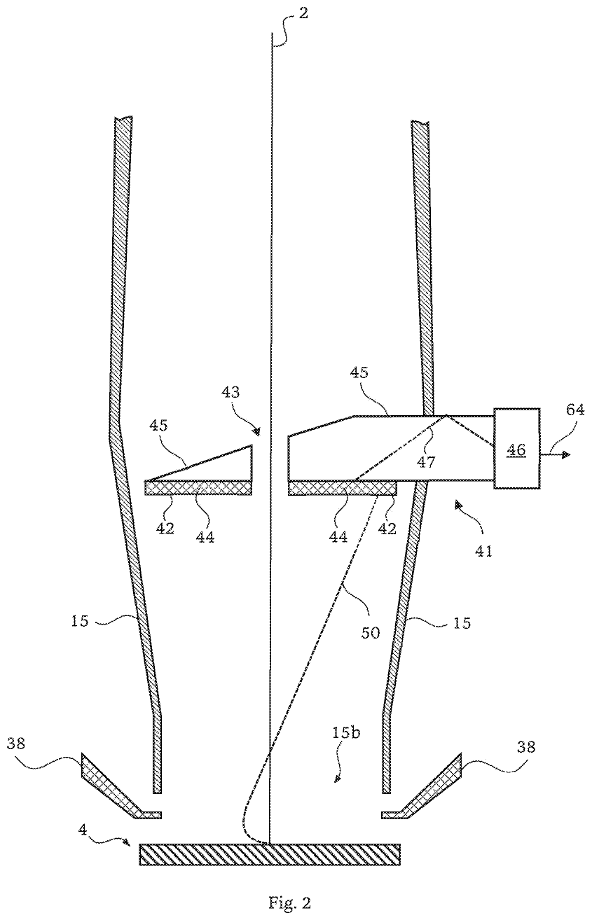

The electron beam microscope 1 furthermore comprises a detector 41 configured to output a detection signal based on electrons incident on a detection area 42 of the detector 41. FIG. 2 shows a schematic illustration of the detector 41 and of a part of the electron beam column 10. As shown in FIG. 2, the detector 41 comprises a scintillator 44, a light guide 45 and a light detector 46. The detection area 42 of the detector 41 is a surface of the scintillator 44. The detection area 42 of the detector 41 is arranged in the interior 16 of the beam tube 15. The scintillator 44 is arranged (at least partially) in the interior 16 of the beam tube 15. The detection area 42 and the scintillator 44 are arranged along the propagation direction of the electron beam 3 between the first opening 15a of the beam tube 15 and the second opening 15b of the beam tube 15. For example, the detection area 42 and the scintillator 44 are arranged along the central axis 2 of the electron beam column 10 between the first opening 15a of the beam tube 15 and a location of maximum strength of the field generated by the objective lens 30. The detection area 42 at least partially surrounds (i.e. partially or completely surrounds) a clearance 43 through which the electron beam 3 passes when the electron beam column 10 is in operation. The detection area 42 surrounds the clearance 43 (in part or in full) along a circumferential direction about the central axis 2. For example, the clearance 43 is formed by an opening in the detection area 42 that extends through the detection area 42. Alternatively, the detection area 42 can have for example a split by way of a gap that extends through the detection area 42 along the central axis 2.

The detection area 42 can face the work region 6. The detection area 42 of the detector 41 is arranged such that electrons (secondary electrons and backscattered electrons) emitted by the sample 4 can be incident on the detection area 42.

The scintillator 44 is configured to convert electrons 50 emitted by the sample 4 and incident on the detection area 42 or the scintillator 44 into light 47. The light guide 45 is configured to guide the light 47 to the light detector 46. In the example shown, the light guide 45 penetrates through the beam tube 15. Accordingly, the light 47 emitted by the scintillator 44 propagates through the light guide 45 from the interior 16 to outside the electron beam column 10. The light detector 46 is configured to detect the light 47 supplied to the light detector 46 by the light guide 45. For this purpose, the light guide 45 is connected to the light detector 46. However, this is only an example. The detector 41 need only comprise the scintillator 44 and the light detector 46. Further details relating to the detection are described further below.

The detection signal of the detector 41 is generated by the light detector 46. The detection signal of the detector 41 is transmitted to a controller 61 by a signal line 64 illustrated schematically in FIG. 1.

The scintillator 44 has an energy-dependent conversion efficiency. That means that the conversion efficiency varies as a function of the energy of incidence of electrons. By way of example, the conversion efficiency of the scintillator 44 is less than a first conversion efficiency value from a first energy value to a second energy value, which is greater than the first energy value by at least 100 eV, and is greater than a second conversion efficiency value, which is greater than the first conversion efficiency value by at least 30%, from a third energy value, which is greater than the first energy value by at least 1 keV and at most 10 keV, to a fourth energy value, which is greater than the third energy value by at least 1 keV. For example, the conversion efficiency of the scintillator 44 varies by at least 30% in an energy range having a width of at least 5 keV.

Between the sample 4 and the scintillator 44 of the detector 41, no electric or magnetic field is generated which repels electrons 50 emitted by the sample 4 from the scintillator 44. For example, the electric potential of the sample 4, the electric potential of the beam tube 15 and the electric potential of the terminating stop 38 are set such that electrons emitted by the sample 4 are not prevented from entering the second opening 15b of the beam tube 15. For example, no grid electrode which prevents the electrons emitted by the sample 4 from propagating in the direction of the scintillator 44 is arranged between the second end of the beam tube 15 and the scintillator 44 of the detector 41. Accordingly, a difference between the energy of incidence of the electrons 50 emitted by the sample 4 upon incidence on the scintillator 44 and an emission energy of these electrons is defined substantially only by the electric voltage between the beam tube 15 and the sample 4.

As shown in FIG. 1, the electron beam microscope 1 furthermore comprises a driver system 62. The driver system 62 is configured to generate the electric potentials, voltages and currents used for operating the components of the electron beam microscope 1 and to supply them to the components. For example, the driver system 62 generates the electric potential for the electron source 11, the electric potential for the beam tube 15, the electric potential for the terminating stop 38, the electric potential for the sample 4 and the electric currents for operating the objective lens 30, the condenser lens 21 and the deflection system 35. Consequently, the driver system 62 also generates the acceleration voltage U0 and the electric voltage between the beam tube 15 and the sample 4 (beam tube voltage).

For this purpose, the driver system 62 can comprise one or more voltage and current sources that generate the electric potentials, voltages and currents used for operating the components of the electron beam microscope 1. A line 63 schematically represents all of the electrical lines that are used to supply the electric potentials, voltages and currents from the driver system 62 to the individual components of the electron beam microscope 1.

The electron beam microscope 1 furthermore comprises the controller 61 for controlling the electron beam microscope 1. The controller 61 controls the electron beam column 10, for example, by controlling the driver system 62. The controller 61 can thereby set the individual electric potentials, voltages and currents used for operating the components of the electron beam device 1 in a targeted manner and can thus control the functioning and effect of the components of the electron beam microscope 1. The electric potentials, voltages and currents that are intended to be generated by the driver system 62 can be represented in the controller 61 by corresponding operating parameters. For example, a value of an operating parameter defines a value of an electric potential, of an electric voltage or of an electric current.

The controller 61 can change the functioning and effect of a component of the electron beam microscope 1 by virtue of changing the value of the corresponding operating parameter. The values of the operating parameters can be stored in a memory of the controller 61 and can be changed by a processor of the controller 61. A set of values of operating parameters that is sufficient to operate the electron beam microscope 1 defines a mode of operation of the electron beam microscope 1. Multiple sets of values of operating parameters that define multiple different modes of operation can be stored in the memory of the controller 61. The controller 61 can accordingly operate the electron beam microscope 1 selectively in one of multiple modes of operation. For this purpose, the controller 61 loads the values of the operating parameters of the selected mode of operation from the memory and instructs the driver system 62 to generate the electric potentials, voltages and currents used for operating the components of the electron beam device 1 in accordance with the loaded values of the operating parameters. A user can change the values of the operating parameters of a mode of operation by way of an input device 65.

The controller 61 can be configured to carry out the methods described herein.

The electron beam microscope 1 furthermore comprises at least one input device 65 and at least one output device 66. Examples of an input device 65 include a keyboard, a mouse, and the like. Examples of an output device 66 include a display device, a loudspeaker, and the like. The input device 65 is connected to the controller 61 and configured to receive inputs from an operator or some other external device and to transmit the received inputs to the controller 61. The output device 66 is connected to the controller 61 and configured to output data provided by the controller 61 to an operator or some other external device.

### Method for Operating the Electron Beam Microscope

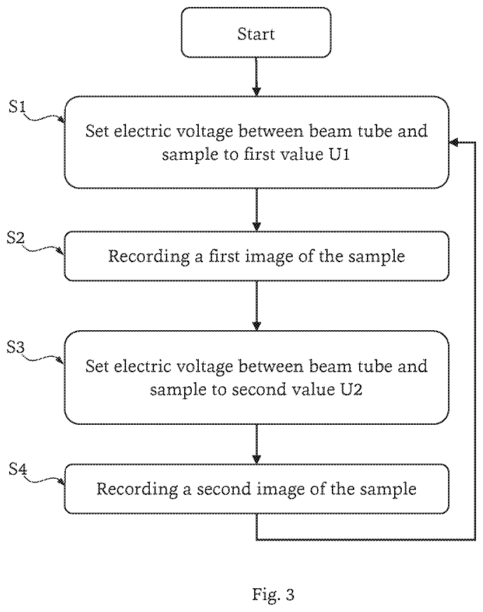

A method for operating the electron beam microscope 1 is described below with reference to FIG. 3.

In order to record a first image (for example a backscattered electron image) of the sample 4, the method comprises steps S1 and S2.

In step S1, the acceleration voltage U0 between the electron source 11 and the sample 4 is set to a value suitable for accelerating the electron beam 3 to the sample 4. Furthermore, the electric voltage between the beam tube 15 and the sample 4 (beam tube voltage) is set to a first value U1 suitable for accelerating electrons 50 emitted by the sample 4 to the beam tube 15 (and thus to the scintillator 44).

In step S2, which is carried out after step S1, a first image of the sample 4 is recorded by the electron beam microscope 1 with the setting undertaken in step S1. That means that the first image is recorded while the set acceleration voltage U0 is applied and the beam tube voltage is applied according to the first value U1. Recording the first image comprises: directing the electron beam 3 successively onto a multiplicity of different locations of the sample 4; and generating the detection signal via the detector 41. The controller 61 associates the various locations and the detection signal and stores this information, thereby obtaining the first image.

During the recording of the first image in step S2, secondary electrons and backscattered electrons are emitted by the sample 4. The secondary electrons and the backscattered electrons are accelerated by an electric field, the strength of which is set by the beam tube voltage, and enter the interior 16 of the beam tube 15 through the terminating stop 38 and the second opening 15b of the beam tube 15. In the interior 16, the secondary electrons and backscattered electrons propagate further and are incident on the detection area 42 of the detector 41, i.e. on a surface of the scintillator 44.

In the scintillator 44, the incident secondary electrons and backscattered electrons are converted into light 47 and the generated light is detected by the light detector 46, which generates the detection signal based on the detected light 47. The detection signal generated by the detector 41 during the recording of the first image substantially consists of two contributions: a first contribution generated by backscattered electrons, and a second contribution generated by secondary electrons. The set value of the beam tube voltage influences the value of the backscattered electron-secondary electron contribution ratio, i.e. the value of the ratio of the first contribution to the second contribution. The value of the backscattered electron-secondary electron contribution ratio when recording the first image is referred to as V1.

In order to record a second image (for example a secondary electron image) of the sample 4, the method comprises steps S3 and S4.

In step S3, which is carried out after step S2, the acceleration voltage U0 is maintained and the beam tube voltage is set to a second value U2. The first value U1 of the beam tube voltage and the second value U2 of the beam tube voltage differ from one another. In order to change the beam tube voltage, the electric potential of the beam tube 15 can be changed. The electric potential of the electron source 11 and the electric potential of the sample 4 can remain unchanged. As a result of changing the beam tube voltage to the value U2, the strength of the electric field between the beam tube 15 and the sample 4 is set to a different value suitable for accelerating electrons 50 emitted by the sample 4 to the beam tube 15.

In step S4, which is carried out after step S3, a second image of the sample 4 is recorded by the electron beam microscope 1 with the setting undertaken in step S3. That means that the second image is recorded while the set acceleration voltage U0 is applied and the beam tube voltage is applied according to the second value U2. For the rest, recording the second image is carried out in the same way as recording the first image.

During the recording of the second image in step S4, secondary electrons and backscattered electrons are emitted by the sample 4. The secondary electrons and the backscattered electrons are accelerated by the electric field, the strength of which is set by the beam tube voltage, and enter the interior 16 of the beam tube 15 through the terminating stop 38 and the second opening 15b of the beam tube 15. In the interior 16, the secondary electrons and backscattered electrons propagate further and are incident on the detection area 42 of the detector 41.

On account of the difference between the first value U1 and the second value U2 of the beam tube voltage, a value V2 different from the value V1 is obtained for the backscattered electron-secondary electron contribution ratio. Accordingly, the second image is generated according to the value V2 of the backscattered electron-secondary electron contribution ratio, which is different from the value V1 of the backscattered electron-secondary electron contribution ratio when recording the first image.

Specifically, the first value U1 and the second value U2 of the beam tube voltage are set such that the value V1 of the backscattered electron-secondary electron contribution ratio when recording the first image is greater than the second value V2 of the backscattered electron-secondary electron contribution ratio when recording the second image. By way of example, the first value U1 and the second value U2 of the beam tube voltage are chosen such that the first value V1 is at least 1.2 times the second value V2, i.e. V1/V2≥K, where K has a value of at least 1.2. However, this is only an example, and K can have a value of at least 1.5 or at least 2 or at least 5 or at least 10. Accordingly, the first image may be referred to as a backscattered electron image and the second image may be referred to as a secondary electron image.

In the present example, the backscattered electron image (first image) is recorded before the secondary electron image (second image). However, this is only an example, and the secondary electron image can be recorded before the backscattered electron image.

Further embodiments of the method

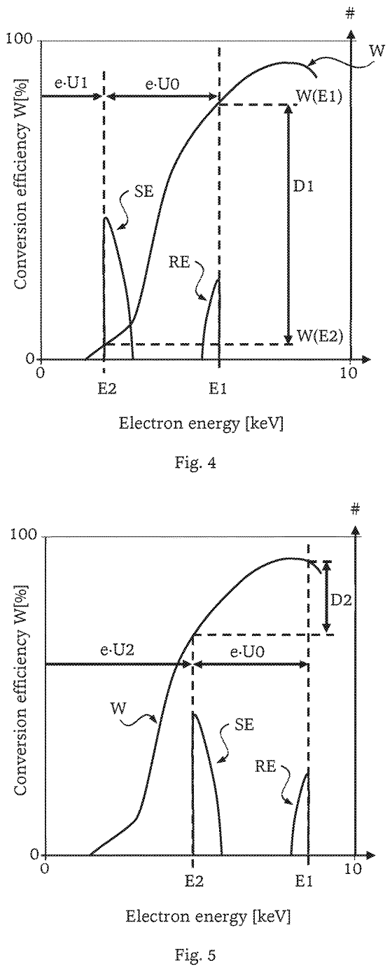

According to one embodiment of the method, in steps S1 and S3, the first value U1 and the second value U2 of the beam tube voltage are chosen such that a value D1 of a conversion efficiency difference when recording the first image is greater than a value D2 of the conversion efficiency difference when recording the second image. This is explained in detail with reference to FIGS. 4 and 5.

FIG. 4 shows an exemplary energy-dependent conversion efficiency W(E) and a spectrum of the energy of incidence of electrons 50 on the scintillator 44 when recording the first image in step S2. FIG. 5 shows the energy-dependent conversion efficiency W(E) and a spectrum of the energy of incidence of electrons 50 on the scintillator 44 when recording the second image in step S4.

With regard to the energy-dependent conversion efficiency W, the horizontal axis in FIGS. 4 and 5 represents the energy of incidence, i.e. the kinetic energy of the electrons 50 when incident on the scintillator 44. The vertical axis represents the conversion efficiency W of the scintillator 44 as a function of the energy of incidence. The conversion efficiency W of the scintillator 44 at a specific energy represents a mean value of a number of photons generated by the scintillator 44 when an electron 50 having the specific energy is incident on the scintillator 44. The conversion efficiency W can have values between 0 and 1. A high conversion efficiency means that an individual electron is converted into a high number of photons. By contrast, a low conversion efficiency means that an individual electron is converted into a small number of photons.

The spectrum of the energy of incidence of electrons 50 on the scintillator 44 when recording the first image as shown in FIG. 4 comprises two components: A curve denoted by the reference sign SE represents a number of secondary electrons that were incident on the scintillator 44 during the recording of the first image as a function of the energy of incidence of the secondary electrons on the scintillator 44. A curve denoted by the reference sign RE represents a number of backscattered electrons that were incident on the scintillator 44 during the recording of the first image as a function of the energy of incidence of the backscattered electrons on the scintillator 44.

The energy of incidence of the secondary electrons on the scintillator 44 is substantially the sum of the emission energy of the secondary electrons (approximately 0 V to 100 V) and the energy which is absorbed as a result of the acceleration in the electric field generated by the beam tube voltage between the sample 4 and the beam tube 15 (i.e. e·U1, where e is the absolute value of the elementary charge of the electron).

The energy of incidence of the backscattered electrons on the scintillator 44 is substantially the sum of the emission energy of the backscattered electrons (which is substantially equal to the landing energy of the electrons of the electron beam 3 on the sample 4 and substantially corresponds to e·U0) and the energy which is absorbed as a result of acceleration in the electric field generated by the beam tube voltage between the sample 4 and the beam tube 15 (i.e. e·U1, where e is the absolute value of the elementary charge of the electron). The energy of incidence of the backscattered electrons on the scintillator 44 therefore corresponds approximately to a product of the electron elementary charge and an electric voltage between the beam tube 15 and the electron source 11.

The conversion efficiency difference represents a difference between the conversion efficiency W(E1) of the scintillator 44 at a first energy E1 and the conversion efficiency W(E2) of the scintillator 44 at a second energy E2, i.e. W(E1)−W(E2). The first energy E1 is defined as the product of the electron elementary charge and the electric voltage between the beam tube 15 and the electron source 11. The first energy is thus a typical energy of incidence of backscattered electrons on the scintillator 44 when recording an image. The second energy E2 is defined as the product of the electron elementary charge and the electric voltage between the beam tube 15 and the sample 4 (beam tube voltage). The second energy is thus a typical energy of incidence of secondary electrons on the scintillator 44 when recording an image.

As shown in FIG. 4, the first energy E1 when recording the first image is e·(U0+U1) and the second energy E2 when recording the first image is e·U1, where e is the absolute value of the elementary charge of the electron. The conversion efficiency difference when recording the first image has a value

D1=W(e·(U0+U1))−W(e·U1)

As shown in FIG. 5, the first energy E1 when recording the second image is e·(U0+U2) and the second energy E2 when recording the second image is e·U2, where e is the absolute value of the elementary charge of the electron. The conversion efficiency difference when recording the second image has a value D2=W(e·(U0+U2))−W(e·U2) .

As can be discerned from the comparison of FIGS. 4 and 5, the value D1 of the conversion efficiency difference when recording the first image is greater than the value D2 of the conversion efficiency difference when recording the second image. That means that backscattered electrons are converted into light by the scintillator 44 more efficiently than secondary electrons by way of a suitable choice of the beam tube voltage when recording the first image, compared with the conversion when recording the second image. Accordingly, the first image may be referred to as a backscattered electron image and the second image may be referred to as a secondary electron image.

According to a further embodiment, the first value U1 and the second value U2 of the beam tube voltage are chosen such that the value D1 of the conversion efficiency difference when recording the first image is at least 1.2 times the value D2 of the conversion efficiency difference when recording the second image. This is only an example. The value D1 can be at least 1.5 times or at least 2 times or at least 3 times the value D2.

According to a further embodiment, the first value U1 and the second value U2 of the beam tube voltage are chosen such that a value W1 of a conversion efficiency ratio when recording the first image is greater than a value W2 of the conversion efficiency ratio when recording the second image. The conversion efficiency ratio denotes a ratio of the conversion efficiency W(E1) at the first energy E1 to the conversion efficiency W(E2) at the second energy E2. Accordingly, the value W1 is the value of the ratio of the conversion efficiency W(E1) at the first energy E1 when recording the first image to the conversion efficiency W(E2) at the second energy E2 when recording the first image; and the value W2 is the value of the ratio of the conversion efficiency at the first energy E1 when recording the second image to the conversion efficiency at the second energy E2 when recording the second image.

For example, the first value U1 and the second value U2 of the beam tube voltage are chosen such that the value W1 of the conversion efficiency ratio when recording the first image is at least 1.5 times, for example at least 2 times or at least 5 times, the value W 2 of the conversion efficiency ratio when recording the second image.

In the example shown in FIG. 4, the conversion efficiency W(E1) at the first energy E1 when recording the first image is about 80%, and the conversion efficiency W(E2) at the second energy E2 when recording the first image is about 5%. Accordingly, the value W1 is about 80% /5%=16. In the example shown in FIG. 5, the conversion efficiency W(E1) at the first energy E1 when recording the second image is about 90%, and the conversion efficiency W(E2) at the second energy E2 when recording the second image is about 70%. Accordingly, the value W2 is about 90% /70%≈1.29. In the example shown in FIGS. 4 and 5, the value W1 is therefore approximately (≈16/1.29) 12 times the value W2.

According to a further embodiment, the first value U1 of the beam tube voltage is chosen such that the value W1 of the conversion efficiency ratio when recording the first image is at least 1, such as at least 1.5, for example at least 2 or at least 3. Accordingly, backscattered electrons are converted into light significantly more efficiently than secondary electrons.

According to a further embodiment, recording the first image and recording the second image are carried out directly successively. That means that a time duration between recording the first image in step S2 in FIG. 3 and recording the second image in step S4 in FIG. 3 is relatively short. By way of example, the time duration is less than 2 minutes, for example less than 1 minute or less than 30 seconds.

According to a further embodiment, recording the first image and recording the second image are carried out repeatedly. FIG. 3 shows an arrow from step S4 to step S1, which indicates that the method can be repeated after step S4 starting from step S1. A time period between recording the second image in step S4 and subsequently recording the first image in step S2 can be relatively short. By way of example, the time duration is less than 2 minutes, for example less than 1 minute or less than 30 seconds.

According to a further embodiment, the acceleration voltage U0 is chosen such that the electron beam 3 is accelerated to the sample 4, and the first value U1 and the second value U2 of the beam tube voltage are chosen such that the electrons 50 emitted by the sample 4 are accelerated from the sample 4 to the beam tube 15. Accordingly, the electrons of the electron beam 3 are incident on the sample 4 and the electrons 50 emitted as a result by the sample 4 are accelerated from the sample 4 in the direction of the scintillator 44.

According to a further embodiment, the first value U1 and the second value U2 of the beam tube voltage are greater than 500 V. That means that the acceleration voltage with which the electrons 50 emitted by the sample 4 are accelerated in the direction of the scintillator 44 when recording the first image and the second image is at least 500 V.

According to a further embodiment, the acceleration voltage U0 is greater than 500 V and less than 10 kV. That means that the landing energy of the electrons of the electron beam 3 onto the sample 4 is at least 500 V and is at most 10 keV.

According to a further embodiment, the method furthermore comprises: displaying the first image and the second image, for example simultaneously and/or next to one another, via a display device. The display device is one example of the output device 65. As a result, an operator can view the recorded first image and the recorded second image and compare them with one another.

According to a further embodiment, the method furthermore comprises: automatically setting an electric current supplied to the objective lens 30 by the driver system 62 on the basis of a present value of the beam tube voltage. As a result, the focusing of the electron beam 3 on the sample 4 is adapted in the event of a change in the beam tube voltage such that the electron beam 3 remains focused on the sample 4.

### LIST OF REFERENCE SIGNS

1 Electron beam microscope
2 Central axis
3 Electron beam
4 Sample
5 Sample holder
6 Work region
10 Electron beam column
11 Electron source
13, 14 Housing section
15 Beam tube
15a First opening of the beam tube
15b Second opening of the beam tube
16 Interior
21 Condenser lens
22 Magnetic core
23 Excitation coil
30 Objective lens
31 Magnetic core
32 Excitation coil
33 Gap
35 Deflection system
36, 37 Deflection units
38 Terminating stop
39 Aperture
41 Detector
42 Detection area
43 Clearance
44 Scintillator
45 Light guide
46 Light detector
47 Light
50 Electrons emitted by sample
61 Controller
62 Driver system
63, 64 Line
65 Input device
66 Output device

What is claimed is:

1. A method of operating an electron beam microscope comprising an electron source and a beam tube, the method comprising:
recording a first image of a sample while: i) an electric acceleration voltage is applied between the electron source and the sample; and ii) a beam tube voltage is applied according to a first value, the beam tube voltage being an electric voltage between the beam tube and the sample; and
recording a second image of the sample while the acceleration voltage is applied between the electron source and the sample and the beam tube voltage is applied according to a second value,
wherein recording the first and second images in each case comprises: directing an electron beam provided by the electron source and propagating through an interior of the beam tube successively onto a multiplicity of different locations of the sample and generating a detection signal via a detector, the detector comprising a scintillator and a light detector, the scintillator being in the interior of the beam tube and configured to convert electrons emitted by the sample into light, the light detector being to configured generate the detection signal based on the light generated by the scintillator,
wherein the first and second value a of the beam tube voltage are different from one another and are chosen such that a value of a backscattered electron-secondary electron contribution ratio when recording the first image is greater than the value of the backscattered electron-secondary electron contribution ratio when recording the second image,
wherein the backscattered electron-secondary electron contribution ratio indicates a ratio of a contribution of backscattered electrons to the detection signal to a contribution of secondary electrons to the detection signal when recording a specific image,
wherein secondary electrons are electrons emitted by the sample with an energy of at most 100 eV, and
wherein backscattered electrons are electrons emitted by the sample with an energy which differs from a product of electron elementary charge and the acceleration voltage by at most 500 eV.

2. The method of claim 1, wherein the first value and the second value of the beam tube voltage are chosen such that the value of the backscattered electron-secondary electron contribution ratio when recording the first image is at least 1.2 times the value of the backscattered electron-secondary electron contribution ratio when recording the second image.

3. The method of claim 1,
wherein the first and second values of the beam tube voltage are chosen such that a value of a conversion efficiency difference when recording the first image is greater than a value of the conversion efficiency difference when recording the second image,
wherein the conversion efficiency difference indicates a difference between a conversion efficiency of the scintillator at a first energy and the conversion efficiency of the scintillator at a second energy,
wherein the first energy is a product of the electron elementary charge and an electric voltage between the beam tube, and
wherein the electron source and the second energy is a product of the electron elementary charge and the beam tube voltage.

4. The method of claim 3, wherein the first and second values of the beam tube voltage are chosen such that the value of the conversion efficiency difference when recording the first image is at least 1.2 times the value of the conversion efficiency difference when recording the second image.

5. The method of claim 1,
wherein the first and second values of the beam tube voltage are chosen such that a value of a conversion efficiency ratio when recording the first image is greater than the value of the conversion efficiency ratio when recording the second image,
wherein the conversion efficiency ratio indicates a ratio of a conversion efficiency of the scintillator at a first energy to the conversion efficiency of the scintillator at a second energy,
wherein the first energy is a product of the electron elementary charge and an electric voltage between the beam tube and the electron source, and
wherein the second energy is a product of the electron elementary charge and the beam tube voltage.

6. The method of claim 5, wherein the first and second values of the beam tube voltage are chosen such that the value of the conversion efficiency ratio when recording the first image is at least 1.5 times the value of the conversion efficiency ratio when recording the second image.

7. The method of claim 1,
wherein the first value of the beam tube voltage is chosen such that a value of a conversion efficiency ratio when recording the first image is at least one,
wherein the conversion efficiency ratio indicates a ratio of a conversion efficiency of the scintillator at a first energy to the conversion efficiency of the scintillator at a second energy, and
wherein the first energy is a product of the electron elementary charge and an electric voltage between the beam tube and the electron source and the second energy is a product of the electron elementary charge and the beam tube voltage.

8. The method of claim 3, wherein the conversion efficiency at a specific energy represents a mean value of a number of photons generated by the scintillator when an electron having the specific energy is incident on the scintillator.

9. The method of claim 1, wherein between the sample and the scintillator no electric or magnetic field is generated which repels the electrons emitted by the sample from the scintillator.

10. The method of claim 1, wherein recording the first and second images are performed successively.

11. The method of claim 1, wherein recording the first and second images are part of a sequence which is carried out repeatedly.

12. The method of claim 1, further comprising automatically setting an electric current supplied to an objective lens of the electron beam microscope based on a present value of the beam tube voltage.

13. The method of claim 1,
wherein the acceleration voltage is chosen such that the electron beam is accelerated to the sample, and
wherein the first and second values of the beam tube voltage are chosen such that the electrons emitted by the sample are accelerated from the sample to the beam tube.

14. The method of claim 1, wherein each of the first and second values of the beam tube voltage are greater than 500 V.

15. The method of claim 1, wherein the acceleration voltage is greater than 500 V and less than 10 kV.

16. The method of claim 1, further comprising displaying the first and second images simultaneously next to one another via a display device.

17. The method of claim 3, wherein the first value and the second value of the beam tube voltage are chosen such that the value of the backscattered electron-secondary electron contribution ratio when recording the first image is at least 1.2 times the value of the backscattered electron-secondary electron contribution ratio when recording the second image.

18. The method of claim 4, wherein the first value and the second value of the beam tube voltage are chosen such that the value of the backscattered electron-secondary electron contribution ratio when recording the first image is at least 1.2 times the value of the backscattered electron-secondary electron contribution ratio when recording the second image.

19. The method of claim 5, wherein the first value and the second value of the beam tube voltage are chosen such that the value of the backscattered electron-secondary electron contribution ratio when recording the first image is at least 1.2 times the value of the backscattered electron-secondary electron contribution ratio when recording the second image.

20. An electron beam microscope, comprising:
an electron source configured to provide an electron beam;
a beam tube surrounding an interior, in which the electron beam propagates during operation of the electron beam microscope;
a deflection system configured to deflect the electron beam transversely with respect to a propagation direction of the electron beam;
a detector comprising a scintillator and a light detector, wherein the scintillator is arranged in the interior of the beam tube and is configured to convert electrons emitted by the sample and incident on the scintillator into light, and wherein the light detector is configured to detect the light generated by the scintillator;
a driver system configured to apply an electric acceleration voltage between the electron source and the sample and to apply a variably adjustable electric voltage between the beam tube and the sample; and
a controller configured to control the electron beam microscope to perform the method of claim 1.
